(19) United States
(12) Patent Application Publication
(10) Pub. No.: US 2024/0111001 A1
(43) Pub. Date: Apr. 4, 2024

(54) FLUXGATE MAGNETIC SENSOR

(71) Applicant: TEXAS INSTRUMENTS INCORPORATED, Dallas, TX (US)

(72) Inventors: Preetinder Garcha, RICHARDSON, TX (US); Srinath Ramaswamy, MURPHY, TX (US); Viola Schaeffer, Freising (DE)

(21) Appl. No.: 17/956,758

(22) Filed: Sep. 29, 2022

(51) Int. Cl. G01R 33/04; G01R 33/00

(52) U.S. Cl. CPC G01R 33/04; G01R 33/0017

(57) ABSTRACT

In some examples, an apparatus comprises a first coil, a second coil, a control circuit, and a processing circuit. The second coil is magnetically coupled to the first coil. The control circuit has a signal output coupled to the first coil, and a control output, and the control circuit configured to: responsive to a state of the control input, select a field strength level from a set of discrete field strength levels; and provide a first signal representing the selected field strength level at the signal output. Also, the processing circuit has processing inputs and a processing output, the processing inputs coupled to the second coil, the processing output coupled to the control input, and the processing circuit configured to, responsive to a second signal across the processing inputs, set a state of the processing output representing a polarity of a magnetic field sensed by the second coil.

### BACKGROUND

Magnetic sensors are used in a broad range of applications, such as Internet-of-Thing (IoT), medical devices, automotive, handheld devices (e.g., smart phones and tablets), and appliances. The magnetic sensors can support various types of measurements for those applications, such as measuring position/movement, electrical current, and torque. For many of these applications, it is desirable to have a magnetic sensor to have a low power consumption to improve battery life, and to have high sensitivity and high linearity to increase measurement precision.

### SUMMARY

An apparatus comprises: a first coil, a second coil, a control circuit, and a processing circuit. The second coil is magnetically coupled to the first coil. The control circuit has a control input and a signal output, and the signal output is coupled to the first coil. The control circuit is configured to: responsive to a state of the control input, select a field strength level from a set of discrete field strength levels; and provide a first signal representing the selected field strength level at the signal output. The processing circuit has processing inputs and a processing output, the processing inputs coupled to the second coil, the processing output is coupled to the control input. The processing circuit is configured to, responsive to a second signal across the processing inputs, set a state of the processing output representing a polarity of a magnetic field sensed by the second coil.

An apparatus comprises a control circuit and a processing circuit. The control circuit has a control input and a compensation magnetic field control output, and the control circuit configured to: responsive to a state of the control input, select a field strength level from a set of discrete field strength levels; and provide a first signal representing the selected field strength level at the compensation magnetic field control output. The processing circuit has a magnetic field sensing input and a processing output, the processing output coupled to the control input, and the processing circuit configured to, responsive to a second signal at the magnetic field sensing input, set a state of the processing output representing a polarity of a magnetic field.

In a method, a first one of a first signal is received from a first coil. The first one of the first signal represents at least one of: a polarity of a first magnetic field, or whether the first magnetic field saturates a region surrounded by the first coil. Responsive to the polarity of the first magnetic field, a field strength level is selected from a set of discrete field strength levels, and a second signal representing the selected field strength level is provided to a second coil that surrounds the region. After the second signal is provided, a second one of the first signal representing a polarity of a second magnetic field is received from the first coil. Responsive to the polarity of the second magnetic field, a third signal is provided to represent whether a strength of the first magnetic field exceeds the selected field strength level.

### BRIEF DESCRIPTION OF THE DRAWINGS

FIG. 1 is a schematic diagram of an example sensor system including a magnetic sensor and a processing circuit.

FIG. 2 is a schematic diagram of an example sensor system including a fluxgate magnetic sensor.

FIG. 3, FIG. 4, and FIG. 5 include graphs that illustrate example operations of the sensor system of FIG. 2.

FIG. 6 includes a graph that illustrates an example relationship between magnetic field strength and the output of a fluxgate magnetic sensor.

FIG. 7 is a schematic diagram of an example sensor system including a fluxgate magnetic sensor.

FIG. 8 includes graphs that illustrate example operation of the sensor system of FIG. 7.

FIG. 9 is a schematic diagram of an example sensor system including a fluxgate magnetic sensor.

FIG. 10 includes a graph that illustrates an example transfer characteristic of a fluxgate switch provided by the example sensor system of FIG. 9.

FIG. 11A, FIG. 11B, and FIG. 11C include a flowchart of example operations of a fluxgate switch provided by the sensor system of FIG. 9.

FIG. 12 illustrates graphs of example transfer characteristics of the fluxgate magnetic sensor of FIG. 9 during the operations described in FIGS. 11A-11C.

FIG. 13 is a schematic of internal components of the sensor system of FIG. 9.

FIG. 14, FIG. 15, and FIG. 16 are graphs that illustrate example operations of the sensor system of FIG. 9.

FIG. 17 is a flowchart of a method of measuring a magnetic field.

The same reference numbers or other reference designators are used in the drawings to designate the same or similar (functionally and/or structurally) features.

### DETAILED DESCRIPTION

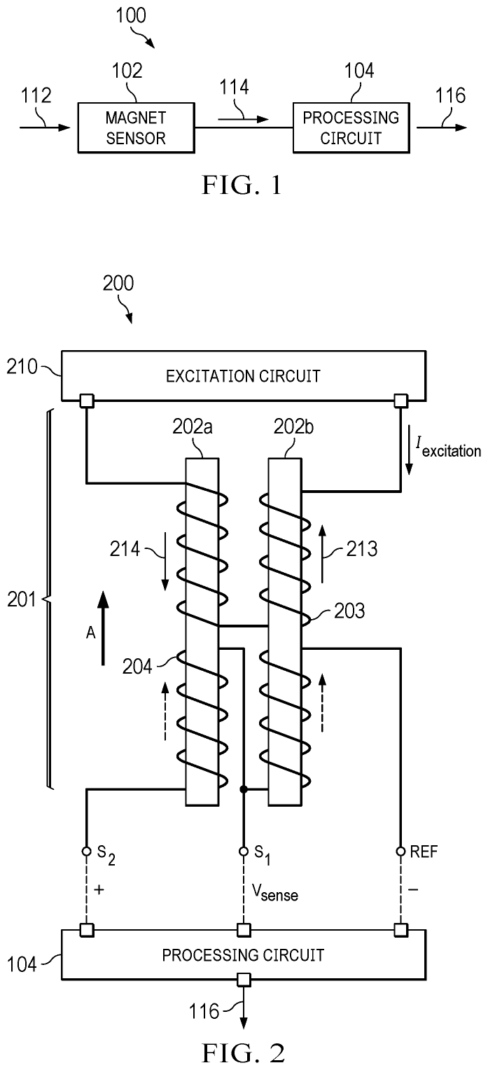

FIG. 1 is a schematic diagram of an example sensor system 100. System 100 includes a magnetic sensor 102 and a processing circuit 104. Magnetic sensor 102 can sense a magnetic field 112 and generate a sense signal 114. Sense signal 114 can be include a voltage signal and/or a current signal, and can indicate a polarity and/or a strength of magnetic field 112. Processing circuit 104 can process sense signal 114 to provide a result signal 116. For example, in a case where system 100 is to support a position of an object that emits magnetic field 112, processing circuit 104 can process sense signal 114 to determine the strength of magnetic field 112 sensed by magnetic sensor 102. Processing circuit 104 can then determine a distance between the object and magnetic sensor based on the magnetic field strength. The magnetic field strength can also reflect a magnetic flux density.

There are various types of magnetic sensors. One type of magnetic sensor is a Hall sensor, which can detect the presence and magnitude of a magnetic field using the Hall effect. A Hall sensor can include a strip of metal to conduct a current. The presence of a magnetic field perpendicular to the flow of the current in the strip can produce a voltage across the strip. The voltage is proportional to the strength of the magnetic field.

Another type of magnetic sensor is a fluxgate magnetic sensor. Compared with a Hall sensor, a fluxgate magnetic sensor can have a significantly higher sensitivity, lower drift, and lower noise, all of which can improve the measurement precision of the magnetic sensor. A fluxgate magnetic sensor can include an excitation coil and a sense coil. In some examples, the excitation coil and the sense coil can surround a core. The excitation coil and the sense coil can be magnetically coupled. An excitation circuit can provide a current pulse in the excitation coil, which generates internal magnetic fields to magnetically saturate the region surrounded by the excitation coil (e.g., a core or a core region) in alternating and opposing directions. Absent an external magnetic field, the internal magnetic fields can cancel each other. This can lead to a static magnetic flux across the sense coil, and no voltage is induced across the sense coil. If an external magnetic field is present and the external magnetic field propagates through the core region, there can be a net change in the magnetic flux across the sense coil, and the net change in the magnetic flux can induce a voltage across the sense coil. The polarity of the voltage can indicate the polarity of the external magnetic field, and the magnitude of the voltage can indicate the strength/magnitude of the external magnetic field.

In some examples, the fluxgate magnetic sensor can include an air core. In some examples, the core of the fluxgate magnetic sensor can include a highly permeable material, such as iron, to concentrate the magnetic field to be measured. The core can have various shapes and configurations, such as a rod shape or a ring shape. In some examples, the coil windings of the fluxgate magnetic sensor can be encapsulated in a magnetic molding compound to further concentrate the magnetic field to be measured. The magnetic molding compound can encapsulate the core, or can fill the core region surrounded by the excitation coil and by the sense coil.

FIG. 2 illustrates an example of a magnetic sensor system 200. Sensor system 200 includes a fluxgate magnetic sensor 201. Fluxgate magnetic sensor 201 can have a pair of rod cores 202a and 202b, and coil windings that are wrapped around the rod cores. In some examples, the rod cores are absent, and cores 202a and 202b represent core regions surrounded by the coil windings. For the rest of the disclosure, each of cores 202a/202b can represent a core or a core region surrounded by the coil windings. The coil windings can include excitation coil 203 and sense coil 204. Excitation coil 203 can wound in opposite directions on rod cores 202a and 202b, while sense coil 204 can wound in the same direction on rod cores 202a and 202b. Excitation coil 203 can receive an excitation current pulse (labelled I_{excitation} in FIG. 2) from an excitation circuit 210. Sense coil 204 can have terminals s1, s2, and ref. Terminal ref can be coupled to a ground or static voltage source, and terminals s1 and s2 can provide a voltage signal Vₛₑₙₛₑ that represents a magnetic field sensed by sense coil 204. The Vₛₑₙₛₑ voltage signal can represent a difference between a voltage Vₛ₁ at terminal s₁ and a voltage Vₛ₂ at terminal s₂ with respect to a voltage at terminal ref, and can represent sense signal 114 of FIG. 1. The voltage at terminal ref can be a common mode voltage, a ground voltage, etc. Processing circuit 104 can process the Vₛₑₙₛₑ voltage signal to generate result signal 116. Result signal 116 can represent the magnitude of an external magnitude field detected by fluxgate magnetic sensor 201.

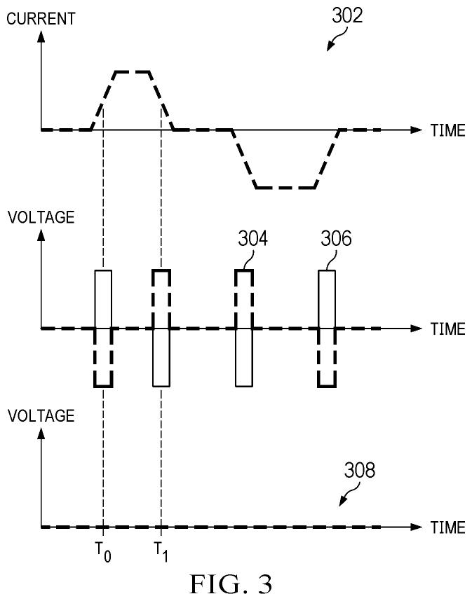

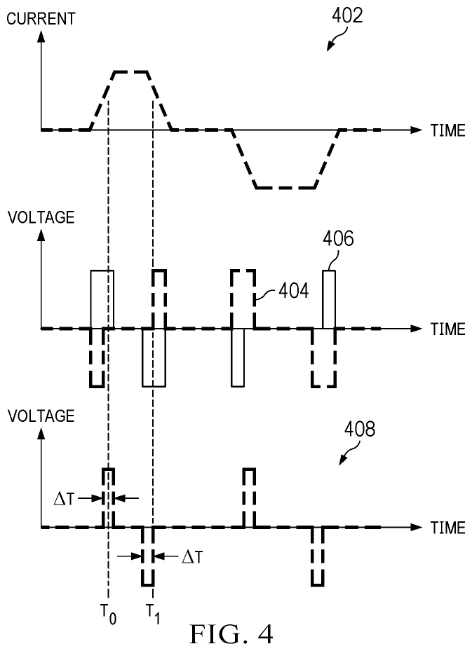

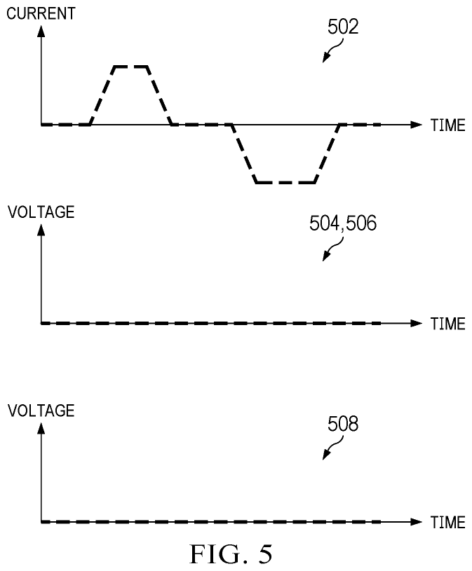

FIG. 3, FIG. 4, and FIG. 5 include graphs that illustrate example operations of sensor system 200. FIG. 3 includes graphs 302, 304, 306, and 308. Graph 302 illustrates an example variation of excitation current I_{excitation} with time. Graph 304 illustrates an example variation of Vₛ₁ voltage at terminal s₁ with time, and graph 306 illustrates an example variation of Vₛ₂ voltage at terminal s2 with time. Graph 308 illustrates an example variation of Vₛₑₙₛₑ voltage with time. FIG. 3 illustrates example variations of Vₛ₁, Vₛ₂, and Vₛₑₙₛₑ voltages when there is no external magnetic field.

Referring to FIG. 2 and FIG. 3, the excitation current can be in the form of current pulses. When the excitation current rises (e.g., at time T₀), it induces a magnetic field 213 that propagates through core 202a in a first direction (labelled A in FIG. 2). The rising excitation current can also generate a magnetic field 214 that propagates through core 202b in the opposite direction of A. Magnetic field 213 can induce a positive Vₛ₂ and a negative Vₛ₁ at time T₀. Also, when the excitation current falls (e.g., at time T₁), the directions (and polarities) of magnetic fields 213 and 214 reverse, which induce a negative Vₛ₂ and a positive Vₛ₁ at time T₁. When the excitation current is static (e.g., between T₀ and T₁), no magnetic field is induced. The magnitude of the excitation current pulses can be large enough so that the resulting strengths of magnetic fields 213 and 214 saturate the respective cores 202a and 202b, and when cores become saturated, the voltages Vₛ₁ and Vₛ₂ become zero, and Vₛ₁ and Vₛ₂ become voltage pulses. In the absence of an external magnetic field, cores 202a and 202b can enter and exit the magnetic saturation state at the same time responsive to the excitation current pulse. Thus, the Vₛ₁ and Vₛ₂ pulses can have the same width, and the Vₛ₁ and Vₛ₂ pulses can cancel each other. Accordingly, the voltage Vₛₑₙₛₑ across sense coil 204 can be at zero, which can indicate that an external magnetic field is absent.

FIG. 4 illustrates example variations of Vₛ₁, Vₛ₂, and Vₛₑₙₛₑ voltages with time when an external magnetic field is present. FIG. 4 includes graphs 402, 404, 406, and 408. Graph 402 illustrates an example variation of excitation current I_{excitation} with time. Graph 404 illustrates an example variation of Vₛ₁ voltage at terminal s₁ with time, and graph 406 illustrates an example variation of Vₛ₂ voltage at terminal s₂ with time. Graph 408 illustrates an example variation of Vₛₑₙₛₑ voltage with time. In a case of an external field propagating in the A direction in cores 202a and 202b, the external magnetic field can add to magnetic field 213 and subtract from magnetic field 214, which causes core 202a to enter the magnetic saturation state sooner than core 202b. Accordingly, the Vₛ₁ pulses at times T₀ and T₁ can have smaller widths than the Vₛ₂ pulses and the Vₛ₁ and Vₛ₂ pulses do not cancel each other, which lead to a set of Vₛₑₙₛₑ pulses across sense coil 204. The phases/polarities of the Vₛₑₙₛₑ pulses can indicate the polarity of the external magnetic field. Also, the duration of each Vₛₑₙₛₑ pulse (labelled ΔT) can indicate the strength of the external magnetic field. Processing circuit 104 can include an integrator to integrate the Vₛₑₙₛₑ pulses to an analog voltage. In some examples, processing circuit 104 can include an analog-to-digital converter (ADC) to digitize the analog voltage and generate result signal 116, which can include a digital value representing the external magnetic field strength.

FIG. 5 illustrates example variations of Vₛ₁, Vₛ₂, and Vₛₑₙₛₑ voltages with time when a large external magnetic field is present, and the large external magnetic field saturates cores 202a and 202b. FIG. 5 includes graphs 502, 504, 506, and 508. Graph 502 illustrates an example variation of excitation current I_{excitation} with time. Graph 504 illustrates an example variation of voltage Vₛ₁ at terminal s₁ with time, and graph 506 illustrates an example variation of voltage Vₛ₂ at terminal s₂ with time. Graph 508 illustrates an example variation of voltage Vₛₑₙₛₑ with time. Because the external magnetic field saturating cores 202a and 202b, no detectable voltage pulse (or voltage pulses having very small amplitudes) is induced at terminals s₁ and s₂ at the transitions of the excitation current pulses, and Vₛ₁ and Vₛ₂ remain at zero or static. The voltage Vₛₑₙₛₑ across sense coil 204 can also be at zero (or static).

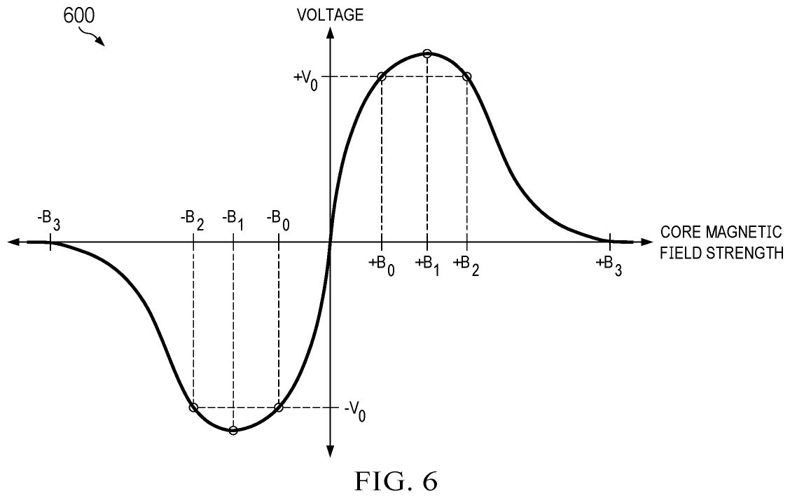

Although a fluxgate magnetic sensor can have a high sensitivity, it can also exhibit significant non-linearity in measuring a large external magnetic field, which can saturate the cores/core regions of fluxgate magnetic sensor, as shown in FIG. 5. FIG. 6 illustrates a graph 600 of an example relationship between an output voltage of a fluxgate magnetic sensor (e.g., result signal 116 of fluxgate magnetic sensor 201) and the strength of a core magnetic field in the core/core region of the fluxgate magnetic sensor (e.g., cores 202a/202b). Graph 600 can represent a transfer characteristic graph of the fluxgate magnetic sensor. The output voltage can be generated by integrating the Vₛₑₙₛₑ pulses. The magnetic field represented in the left and right halves of graph 600 can have opposite polarities, which is also reflected in the opposite polarities of the output voltage the left and right halves of graph 600. For example, the magnetic field represented in the right half of graph 600 can point towards the north, and the magnetic field represented in the left half of graph 600 can point towards the south.

Referring to FIG. 6, with the core magnitude field strength below B₀ (e.g., in the range between −B₀ and +B₀) the output voltage of the fluxgate magnetic sensor can have a linear relationship with the core magnitude field strength, in which the magnitude of the output voltage increases with the core magnitude field strength, and the output voltage can have a one-to-one correspondence with the magnitude field strength. But as the core magnitude field strength increases above B₀ (above +B₀ or below −B₀), the fluxgate magnetic sensor can exhibit substantial non-linearity due to saturation, such that the output voltage no longer has a one-to-one correspondence with the magnitude field strength. For example, the output voltage exhibits a quadratic relationship with the core magnetic field strength within a range between B₀ and B₂, where the output voltage increases with the core magnetic field strength between B₀ and B₁, and the output voltage decreases as the core magnetic field strength increases from B₁ to B₂. The output voltage can be equal to V₀ with the core magnetic field strength being at B₀ or B₂ (+V₀ at +B₀ or +B₂, −V₀ at −B₀ or −B₂). Also, with the core magnetic field strength greater than B₂, the magnitude of the output voltage can continue to decrease as the magnetic field strength increases. The output voltage can be at zero with core magnetic field strength being greater than B₃, where the core of the fluxgate magnetic sensor can be permanently saturated by the core magnetic field, as illustrated in FIG. 5. Accordingly, the output voltage of a fluxgate magnetic sensor can represent an unambiguous measurement of a core magnetic field strength up to B₁. Beyond B₁, a particular output voltage provided by the fluxgate magnetic sensor can indicate two possible core magnetic field strength values.

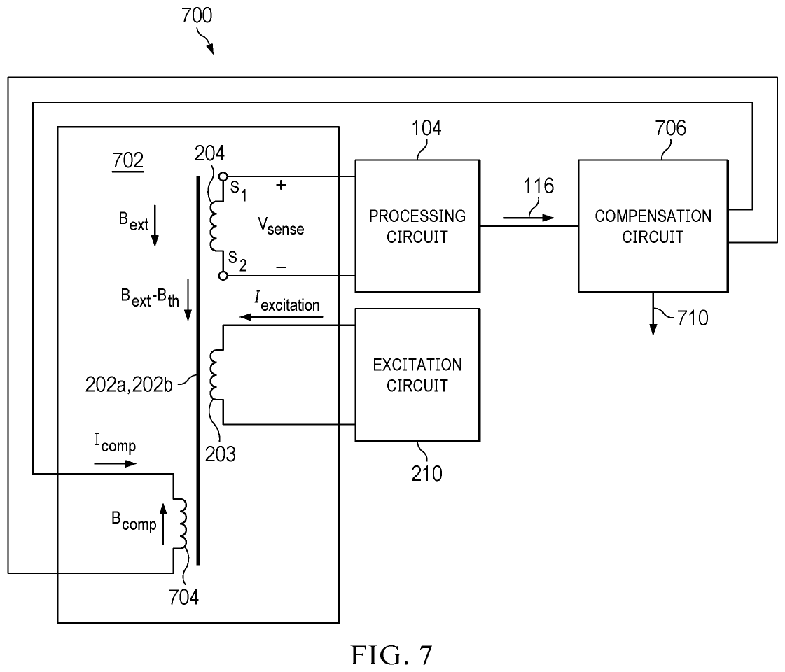

FIG. 7 illustrates an example of sensor system 700 that can provide improved linearity in measuring a large external magnetic field. Referring to FIG. 7, sensor system 700 includes a fluxgate magnetic sensor 702, which includes a compensation coil 704 and a compensation circuit 706, in addition to cores 202a/202b (or core regions), excitation coil 203, and sense coil 204 of FIG. 2. In some examples, cores 202a/202b can include an air core or a metal core (e.g., iron core). In some examples, the coil windings (e.g., excitation coil 203, sense coil 204, and compensation coil 704) of fluxgate magnetic sensor 70 can be encapsulated in a magnetic molding compound to concentrate the external magnetic field to be measured. The magnetic molding compound can also encapsulate the core if the core is present, or can fill the core region surrounded by the coil windings if the core is absent.

Sensor system 700 can perform a feedback operation to iteratively estimate the external magnetic field strength. Specifically, compensation coil 704 can receive a compensation current (labelled I_{comp}) from compensation circuit 706 and generate a compensation magnetic field having a strength of B_{comp} responsive to the compensation current. The compensation magnetic field can have an opposite polarity to the external magnetic field having a strength of Bₑₓₜ, so that the core magnetic field in core 201/202 having a net strength of a difference between Bₑₓₜ and B_{comp} (Bₑₓₜ−B_{comp}). As part of the feedback mechanism, compensation circuit 706 can receive result signal 116 from processing circuit 104. Result signal 116 can include a digital value representing the net strength Bₑₓₜ−B_{comp}. Compensation circuit 706 can include a digital-to-analog converter (DAC) to generate compensation current I_{comp} iteratively based on result signal 116 until the net strength Bₑₓₜ−B_{comp} reaches zero. Compensation circuit 706 can then provide an output signal 710 representing the final value of I_{comp} as an estimation/measurement of the external magnetic field strength Bₑₓₜ. Because the core magnetic field has a reduced net strength Bₑₓₜ−B_{comp}, the core is less likely to be saturated even when a large external magnetic field is present. The core magnetic field can be within a range where the output of the fluxgate magnetic sensor is more linear (e.g., below B₀ of FIG. 6) or where the output can provide an unambiguous measurement of the core magnetic field (e.g., below B₁ of FIG. 6). Accordingly, the range of measurable magnetic field strength can be extended.

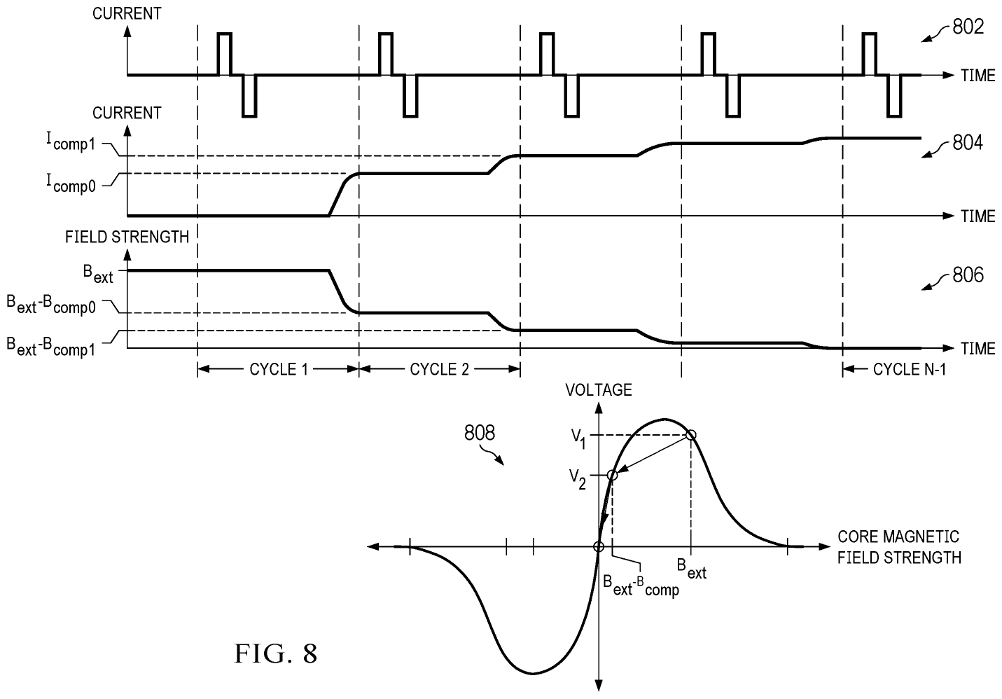

FIG. 8 include graphs that illustrate an example feedback operation of sensor system 700. FIG. 8 includes graphs 802, 804, 806, and 808. Graph 802 illustrates an example variation of excitation current I_{excitation} with time. Graph 804 illustrates an example variation of compensation current I_{comp} with time. Graph 806 illustrates an example variation of core magnetic field strength with time. Graph 808 illustrates a transfer characteristic graph of fluxgate magnetic sensor 700 denoting a set of output voltages and core magnetic field strengths during the example feedback operation.

Referring to FIG. 8, fluxgate magnetic sensor 700 can measure an external magnetic field strength Bₑₓₜ in a feedback operation that spans N measurement cycles, including measurement cycles 1, 2, up to cycle N−1. In the example of FIG. 8, excitation circuit 210 can provide a pair of excitation current pulses having opposite polarities. In measurement cycle 1, compensation circuit 706 initially provides zero compensation current. In the presence of an external magnetic field, the core magnetic field can have a strength of Bₑₓₜ. Referring to graph 808, Bₑₓₜ is in a range where a particular output voltage provided by fluxgate magnetic sensor 700 can indicate two possible core magnetic field strength values. Sense coil 204 can generate Vₛₑₙₛₑ pulses representing Bₑₓₜ.

Towards the end of measurement cycle 1, processing circuit 104 can process the Vₛₑₙₛₑ pulses and provide an output voltage V₁ as part of result signal 116 to compensation circuit 706. Compensation circuit 706 may determine that output voltage V₁ represents a magnetic field strength of B_{COMP0} instead of Bₑₓₜ from the transfer characteristic graph represented by graph 808. Accordingly, compensation circuit 706 can provide a compensation current I_{comp0} to compensation coil 704, which can then generate a compensation magnetic field having the strength of B_{comp0}. The compensation magnetic field can combine with the external magnetic field, so that the core/combined magnetic field strength is reduced to become Bₑₓₜ−B_{comp0}.

In measurement cycle 2, sense coil 204 can generate Vₛₑₙₛₑ pulses representing the net strength Bₑₓₜ−B_{comp0}. Towards the end of measurement cycle 2, processing circuit 104 can process the Vₛₑₙₛₑ pulses and provide an output voltage V₂ as part of result signal 116 to compensation circuit 706. Based on the output voltage V₂, compensation circuit 706 determines that the previous compensation current I_{comp0} does not generate sufficient magnetic field to completely cancel out Bₑₓₜ, and increase the compensation current to I_{comp1} to further reduce the output voltage of processing circuit 104. Compensation circuit 706 can determine I_{comp1} by first determining the additional amount of compensation current to increase the compensation magnetic field strength by Bₑₓₜ−B_{comp0}, and adding the amount of compensation current to I_{comp0}. Compensation circuit 706 can provide compensation current I_{comp1} to compensation coil 704, which can then generate a compensation magnetic field having the strength of B_{comp1}. The compensation magnetic field can combine with the external magnetic field, so that the core/combined magnetic field strength is reduced to become Bₑₓₜ−B_{comp1}.

In subsequent measurement cycles, compensation circuit 706 can continue increasing the compensation current to further reduce core magnetic field strength. Convergence is reached in cycle N−1 where the core/combined magnetic field strength is below a threshold, which indicates that the external magnetic field and the compensation magnetic field have almost the same strength, and the strength difference is below the threshold. Compensation circuit 706 can then provide output signal 710 based on the final compensation current value to represent a measurement of the external magnetic field strength Bₑₓₜ.

Although the feedback operation described in FIG. 8 can improve the linearity of fluxgate magnetic sensor 700 and extend the measurable magnetic field strength range, the feedback operation can be slow and consume a lot of power. Specifically, the feedback operation may need a large number of measurement cycles to achieve convergence, which increases the response time in measuring the magnetic field. Also, having excitation circuit 210, processing circuit 104, and compensation circuit 706 to operate over the large number of measurement cycles can lead to huge power consumption. Accordingly, the feedback operation may not be suitable for low power applications (e.g., IoT device, handheld device, etc.) and for high speed applications that may require fast measurement of magnetic field (e.g., gaming controller, collision avoidance system, etc.).

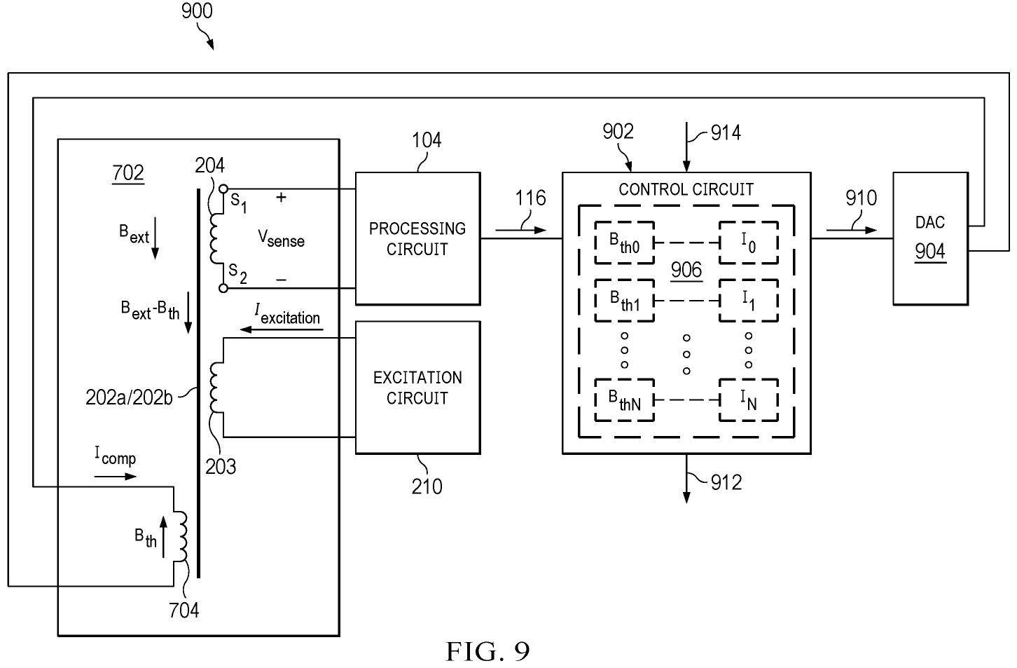

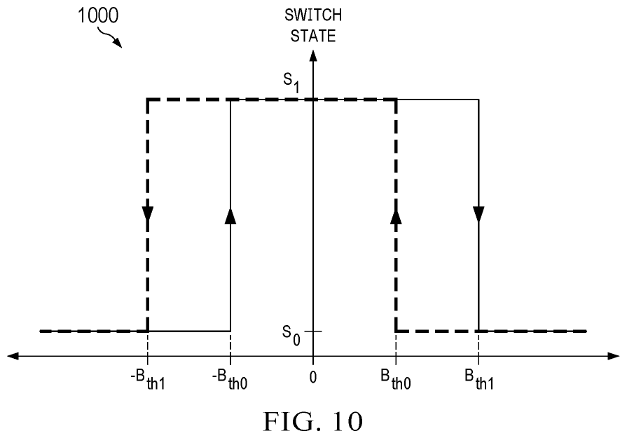

FIG. 9 illustrates an example of sensor system 900 that can address at least some of the issues described above. Referring to FIG. 9, sensor system 900 can include a control circuit 902 and a DAC 904, in addition to processing circuit 104, excitation circuit 210, and fluxgate magnetic sensor 702 of FIG. 7. Control circuit 902 can include circuits (e.g., registers, memory, etc.) to store a mapping table 906 that maps a sets of compensation current settings (represented by I₀, I₁, and I_{N} in FIG. 9), to a set of discrete magnetic field strength levels (represented by Bₜₕ₀, Bₜₕ₁, and B_{thN} in FIG. 9). Control circuit 902 can select one of the compensation current settings from mapping table 906, and provide the selected compensation current setting in the form of digital signals to DAC 904 as a control signal 910. DAC 904 can provide a compensation current I_{comp} responsive to the compensation current setting. In some examples, sensor system 900 can include a voltage-to-current (V-to-I) circuit instead of DAC 904. Control circuit 902 can generate the compensation current setting in the form of an analog voltage signal, and the V-to-I circuit can generate a compensation current I_{comp} responsive to the analog voltage signal representing the compensation current setting. Compensation coil 203 can generate a compensation magnetic field having a field strength Bₜₕ, with the field strength equal to one of the strength levels (e.g., one of Bₜₕ₀, Bₜₕ₁, and B_{thN}) mapped to the compensation current setting in mapping table 906.

The compensation magnetic field generated by compensation coil 203 can combine with the external magnetic field to provide a combined/core magnetic field, which can be sensed by sense coil 204. Processing circuit 104 can provide result signal 116 representing a polarity of the core magnetic field, which can also indicate whether the external magnetic field strength exceeds or is below the compensation magnetic field strength. Control circuit 902 can also maintain a record of previously-selected strength levels and their compensation current settings. Responsive to result signal 116, control circuit 902 can select a different compensation current setting from mapping table 906 to increase the compensation magnetic field strength if the external magnetic field strength exceeds the compensation magnetic field strength.

Control circuit 902 can also stop the comparison operation and the measurement operation if the external magnetic field strength is between two consecutive compensation magnetic field strength levels in mapping table 906, or if the entire set of compensation current settings has been traversed and the external magnetic field strength exceeds the maximum magnetic field strength level in mapping table 906. Control circuit 902 can then provide an output signal 912 as a measurement of the external magnetic field strength. Output signal 912 can indicate, for example, a range of the external magnetic field strength (e.g., between two consecutive compensation magnetic field strength levels in mapping table 906), or whether the external magnetic field strength exceeds the maximum magnetic field strength level in mapping table 906.

In some examples, control circuit 902 (and sensor system 900) can switch between an active state and a sleep state. In the active state, control circuit 902 can enable processing circuit 104, excitation circuit 210, and DAC 904 to measure an external magnetic field strength. In the sleep state, control circuit 902 can disable processing circuit 104, excitation circuit 210, and DAC 904 to reduce power consumption. Control circuit 902 can enter the sleep state after completing a measurement of the external magnetic field strength, and can exit the sleep state to start a new measurement responsive to a wake-up signal 914. In some examples, control circuit 902 can receive wake-up signal 914 as a periodic signal (e.g., a clock signal) to exit the sleep state periodically, so that sensor system 900 can detect and measure an external magnetic field periodically. In some examples, control circuit 902 can receive wake-up signal 914 from a user-controllable input interface (e.g., a mechanical switch) and can exit the sleep state responsive to a user input.

The magnetic field measurement operations of sensor system 900 can reduce response time and power consumption, while providing measurements with improved linearity and accuracy. Specifically, instead of iteratively determining the strength of a compensation magnetic field that matches (and completely cancels) the external magnetic field, as described in FIG. 8, sensor system 900 can compare the external magnetic field strength against a set of discrete strength levels to generate an output, and stops the comparison operation if the external magnetic field strength is lower than a particular strength level, or if the entire set of strength levels have been traversed. Accordingly, the total number of measurement cycles to complete the comparison operation can be reduced, which can reduce power consumption and the response time in providing the measurement result.

Also, compared with a case where no compensation magnetic field is generated to at least partially cancel the external magnetic field, as described in FIG. 2, sensor system 900 can generate compensation magnetic fields of discrete strength levels to combine with the external magnetic field to reduce the core magnetic field strength. Such arrangements can reduce the core magnetic field strength to be within a range where the output of the fluxgate magnetic sensor is linear. This can reduce core saturation and improve the linearity and accuracy of the magnetic field measurement operation.

In some examples, sensor system 900 can be configured as an omnipolar switch that can change states according to the strength and polarity of an external magnetic field. The state of the omnipolar switch can provide a measurement of the magnetic field. The omnipolar switch can also have built-in hysteresis. The switch can enter an on state if an external magnetic field of sufficient strength is present. After the switch is turned on, it can remain in the on-state until the magnetic field is removed, and the switch can enter an off state. The switch can remain in the off state until an external magnetic field of sufficient strength is again present.

FIG. 10 includes a graph 1000 that represents an example transfer characteristic graph of the fluxgate switch. The opposite halves of graph 100 can represent the transfer characteristics of the fluxgate switch in an external magnetic field of opposite polarities. With the external magnetic field having a strength below a first strength level Bₜₕ₀ (below +Bₜₕ₀ in the right half or above −Bₜₕ₀ in the left half), the switch can have a state of S₁, which can represent a logical one or an on-state. Also, with the external magnetic field having a strength above a second above a second strength level Bₜₕ₁ (above +Bₜₕ₁ in the right half or below −Bₜₕ₁ in the left half), the switch can have a state of S₀, which can represent a logical zero or an off-state.

Also, the switch can have built-in hysteresis and can have different switching thresholds depending on whether the external magnetic field strength increases or decreases. For example, for an increasing external magnetic field, if the external magnetic field strength increases above Bₜₕ₁, the switch can change from the S₁ state to the S₀ state. The switch can stay in the S₁ state when the decreasing external magnetic field strength is between Bₜₕ₀ and Bₜₕ₁. Also, for a decreasing external magnetic field, if the external magnetic field strength decreases below Bₜₕ₀, the switch can change from the S₀ state to the S₁ state. The switch can stay in the S₀ state when the increasing external magnetic field strength is between Bₜₕ₀ and Bₜₕ₁.

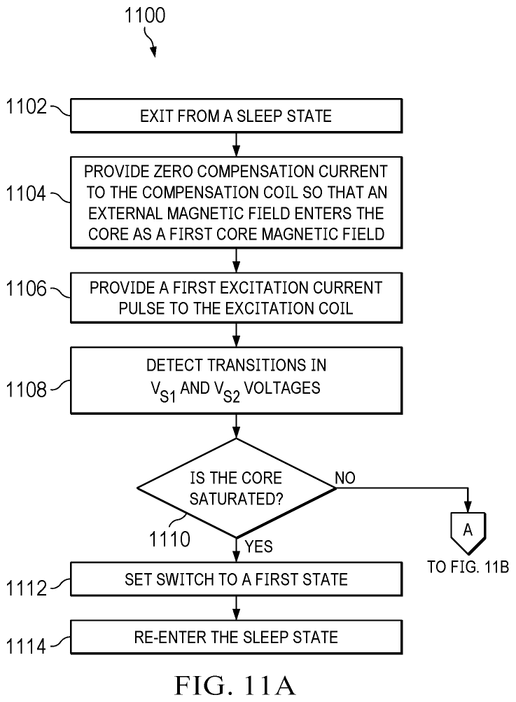

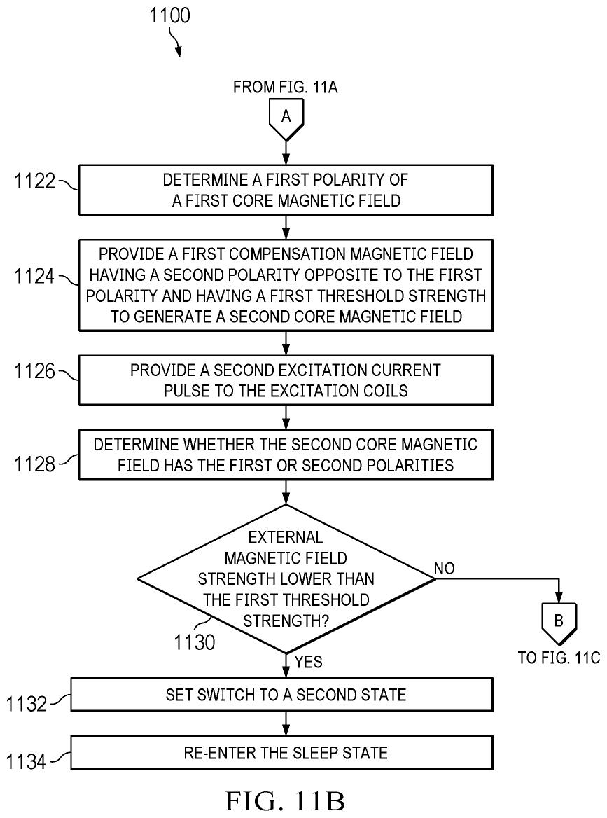

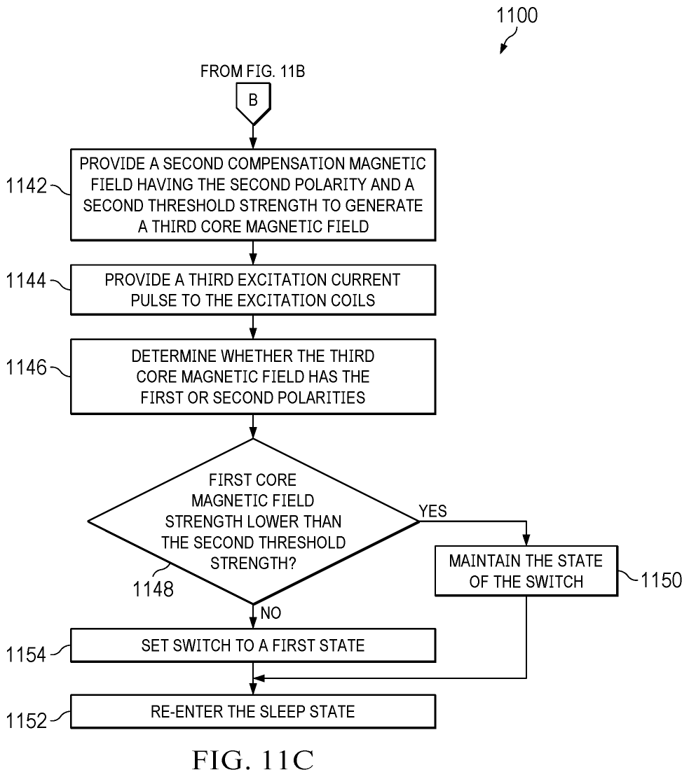

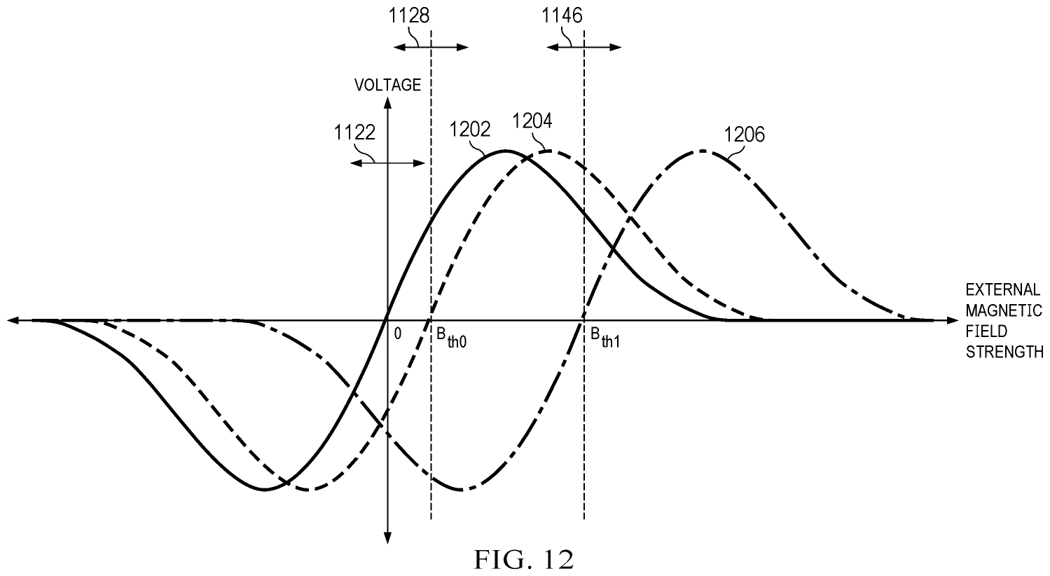

FIG. 11A, FIG. 11B, and FIG. 11C illustrates a flowchart 1100 of example operations performed by sensor system 900 as an omnipolar fluxgate switch, and FIG. 12 illustrates graphs of transfer characteristics of fluxgate magnetic sensor 702 during the operations described in FIGS. 11A-11C. The operations of flowchart 1100 can be performed by control circuit 902 in conjunction with other components of sensor system 900, including fluxgate magnetic sensor 702, processing circuit 104, excitation circuit 210, and DAC 904.

Referring to FIG. 11A, in step 1102, control circuit 902 (and sensor system 900) can exit a sleep state. Sensor system 900 can be in a sleep state where control circuit 902 disables most of the components, including processing circuit 104, excitation circuit 210, and DAC 904 to reduce power consumption. Sensor system 900 can exit the sleep state responsive to wake-up signal 914, which can be a clock signal, or a signal from a user-controllable input interface (e.g., a mechanical switch) representing a user input.

In step 1104, sensor system 900 can provide zero compensation current to compensation coil 704, so that compensation coil 704 does not generate a compensation magnetic field. An external magnetic field that enters the core/core region can become the first core magnetic field, and the first core magnetic field can have the same strength as the external magnetic field. For example, control circuit 902 can provide control signal 910 indicating zero compensation current I_{comp} to DAC 904, which then provides zero I_{comp} to compensation coil 704. An external magnetic field can enter cores 202a/202b as the first core magnetic field.

In step 1106, sensor system 900 can provide a first excitation current pulse to excitation coil 203, such as the excitation current pulses illustrated in FIGS. 3-5. Control circuit 902 can cause excitation circuit 210 to provide the first excitation current pulse in a first measurement cycle. In some examples, control circuit 902 can cause excitation circuit 210 to provide a first pair of excitation current pulses having opposite polarities in the first measurement cycle.

As described above, the excitation current pulse can induce an internal magnetic field that saturates cores 202a/202b. If cores 202a/202b are not saturated by the external magnetic field prior to sensor system 900 providing the first excitation current pulse to excitation coil 203, voltage pulses can be induced on terminals s₁ and s₂, as illustrated in FIGS. 3 and 4. The first core magnetic field can introduce pulse width mismatches between the voltage pulses Vₛ₁ and Vₛ₂, which lead to a set of Vₛₑₙₛₑ pulses across sense coil 204. The pulse width of the Vₛₑₙₛₑ pulses (or a voltage resulted from integrating the Vₛₑₙₛₑ pulses) represents the output of fluxgate magnetic sensor 702 in measuring the external magnetic field. Referring to FIG. 12, the output of fluxgate magnetic sensor 702 can follow the transfer characteristic graph represented by graph 1202, where the output of fluxgate magnetic sensor 702 can be at zero for a zero external magnetic field strength. But if cores 202a/202b (or core regions) have been saturated by the first core magnetic field prior to sensor system 900 providing the first excitation current pulse to excitation coil 203, no voltage pulse is induced on terminals s₁ and s₂, and the voltages at terminals s₁ and s₂, Vₛ₁ and Vₛ₂, can remain static.

In step 1108, sensor system 900 can detect transitions in the Vₛ₁ and Vₛ₂ voltages and determine whether voltage pulses are detected at terminals s₁ and s₂. For example, processing circuit 104 can provide result signal 116 to indicate whether voltage pulse is detected, which can also indicate whether the core (or the core region) is saturated.

In step 1110, sensor system 800 can determine whether saturation of the core (or the core region) is detected when zero compensation magnetic field is provided. If saturation is detected, control circuit 902 can provide output signal 912 representing that the switch is in a first state (e.g., an off state, or S₀ state in FIG. 10), in step 1112. Sensor system 900 can then re-enter the sleep state, in step 1114, and the first measurement cycle (and the measurement operation) ends.

But if saturation is not detected (in step 1110), sensor system 900 can proceed to compare the external magnetic field strength with one or more threshold strengths. Specifically, referring to FIG. 11B, sensor system 900 can proceed to step 1122 and determine a first polarity of the first core magnetic field. Because no compensation magnetic field is provided, the first core magnetic field can have the same strength and the same polarity as the external magnetic field. Processing circuit 104 can provide result signal 116 to indicate the first polarity of the first core magnetic field.

In step 1124, sensor system 900 can provide a first compensation magnetic field having a second polarity opposite to the first polarity and having a first strength level. Specifically, referring to FIG. 6, processing circuit 104 can determine the first polarity of the first core magnetic field based on the polarity of the output voltage from fluxgate magnetic sensor 702, and provide result signal 116 indicating the first polarity. Based on the first polarity as indicated by result signal 116, control circuit 902 can determine an opposite polarity to the first polarity as the second polarity for the first compensation magnetic field. Also, control circuit 902 can refer to mapping table 906 and select a first compensation current setting 10 for the first strength level Bₜₕ₀. Control circuit 902 can then provide control signal 910 indicating the second polarity and including the first compensation current setting 10 to DAC 904. DAC 904 can then provide a compensation current I_{comp} to compensation coil 704 having the magnitude of I₀ and having a flow direction that reflects the second polarity. Responsive to I_{comp}, compensation coil 704 can generate the first compensation magnetic field having the second polarity. Referring to FIG. 9, the first compensation magnetic field can subtract from the external magnetic field/first core magnetic field to become the second core/combined magnetic field having the net strength of Bₑₓₜ−Bₜₕ₀. The second core magnetic field can have the first polarity if Bₑₓₜ exceeds Bₜₕ₀, or the second polarity if Bₑₓₜ is below Bₜₕ₀.

In step 1126, sensor system 900 can provide a second excitation current pulse to excitation coil 203, such as the excitation current pulses illustrated in FIGS. 3-5. Control circuit 902 can cause excitation circuit 210 to provide the second excitation current pulse in a second measurement cycle.

The second excitation current pulse can induce an internal magnetic field that saturates cores 202a/202b, and the second core magnetic field can introduce pulse width mismatches between the voltage pulses Vₛ₁ and Vₛ₂. The pulse width of the Vₛₑₙₛₑ pulses (or a voltage resulted from integrating the Vₛₑₙₛₑ pulses) represents the output of fluxgate magnetic sensor 702 in measuring the second core magnetic field. Referring to FIG. 12, because the second core magnetic field is generated by subtraction of the first compensation magnetic field from the external magnetic field, the output of fluxgate magnetic sensor 702 can follow the transfer characteristic graph represented by graph 1204. In some examples, graph 1204 can center at +Bₜₕ₀ where the output of fluxgate magnetic sensor 702 can be at zero if the external magnetic field has the strength of Bₜₕ₀ and have a particular polarity (e.g., pointing towards the north). In some examples, graph 1204 can center at −Bₜₕ₀, and the output of fluxgate magnetic sensor 702 can be at zero if the external magnetic field has the strength of Bₜₕ₀ but have an opposite polarity (e.g., pointing towards the south).

In step 1128, sensor system 900 can determine whether the second core magnetic field has the first polarity or the second polarity, based on result signal 116. As described above, if Bₑₓₜ (external magnetic field strength or first core magnetic field strength) exceeds Bₜₕ₀, the second core magnetic field can have the first polarity. But if Bₑₓₜ is below Bₜₕ₀, the second core magnetic field can have the second polarity.

In step 1130, if result signal 116 indicates that the external magnetic field strength is below the first strength level (e.g., result signal 116 indicating the second polarity), control circuit 902 can provide output signal 912 representing that the switch is in a second state (e.g., an on state, or S₁ state in FIG. 10), in step 1132. Sensor system 900 can then re-enter the sleep state, in step 1134, and the second measurement cycle ends.

But if result signal 116 indicates that the external magnetic field strength is above the first strength level (e.g., result signal 116 indicating the first polarity), and that a compensation magnetic field having the first strength level has previously been provided, control circuit 902 can proceed to compare the external magnetic field strength with a second strength level Bₜₕ₁. Referring to FIG. 11C, sensor system 900 can provide a second compensation magnetic field having the second polarity and a second strength level, in step 1142.

Specifically, control circuit 902 can refer to mapping table 906 and select a second compensation current setting I₁ for the second strength level Bₜₕ₁. Control circuit 902 can then provide control signal 910 indicating the second polarity and including the second compensation current setting I₁ to DAC 904. DAC 904 can then provide a compensation current I_{comp} to compensation coil 704 responsive to control signal 910, and compensation coil 704 can generate the second compensation magnetic field having the second polarity. Referring to FIG. 9, the second compensation magnetic field can subtract from the external magnetic field/first core magnetic field to become the third core magnetic field having the net strength Bₑₓₜ−Bₜₕ₁. The second core magnetic field can have the first polarity if Bₑₓₜ exceeds Bₜₕ₁, or the second polarity if Bₑₓₜ is below Bₜₕ₁.

In step 1144, sensor system 900 can provide a second excitation current pulse to excitation coil 203, such as the excitation current pulses illustrated in FIGS. 3-5. Control circuit 902 can cause excitation circuit 210 to provide the second excitation current pulse in a second measurement cycle.

The third excitation current pulse can induce an internal magnetic field that saturates cores 202a/202b, and the third core magnetic field can introduce pulse width mismatches between the voltage pulses Vₛ₁ and Vₛ₂. The pulse width of the Vₛₑₙₛₑ pulses (or a voltage resulted from integrating the Vₛₑₙₛₑ pulses) represents the output of fluxgate magnetic sensor 702 in measuring the third core magnetic field. Referring to FIG. 12, because the third core magnetic field is generated by subtraction of the third compensation magnetic field from the external magnetic field, the output of fluxgate magnetic sensor 702 can follow the transfer characteristic graph represented by graph 1206. In some examples, graph 1206 can center at +Bₜₕ₁ where the output of fluxgate magnetic sensor 702 can be at zero if the external magnetic field has the strength of Bₜₕ₁ and points towards the north. In some examples, graph 1204 can center at −Bₜₕ₁, and the output of fluxgate magnetic sensor 702 can be at zero if the external magnetic field has the strength of Bₜₕ₁ and points towards the south.

In step 1146, sensor system 900 can determine whether the third core magnetic field has the first polarity or the second polarity, based on result signal 116. As described above, if Bₑₓₜ (external magnetic field strength or first core magnetic field strength) exceeds Bₜₕ₁, the second core magnetic field can have the first polarity. But if Bₑₓₜ is below Bₜₕ₁, the second core magnetic field can have the second polarity.

In step 1148, if result signal 116 indicates that the external magnetic field strength is below the second strength level (e.g., result signal 116 indicating the second polarity), control circuit 902 can maintain the state of the switch, in step 1150. This can provide the built-in hysteresis where the switch state is maintained as the external magnetic field strength increases or decreases to be within the range between Bₜₕ₀ and Bₜₕ₁. For example, if the prior switch state is S₁ and the external magnetic field is becoming stronger with time, control circuit 902 can maintain the switch state at S₁ when the external magnetic field strength is within the range between Bₜₕ₀ and Bₜₕ₁. Also, if the prior switch state is S₀ and the external magnetic field is becoming weaker with time, control circuit 902 can maintain the switch state at S₀ when the external magnetic field strength is within the range between Bₜₕ₀ and Bₜₕ₁. Control circuit 902 can then reenter the sleep state in step 1152, and the third measurement cycle ends.

Also, if result signal 116 indicates that the external magnetic field strength is above the second strength level (e.g., result signal 116 indicating the first polarity), control circuit 902 can provide output signal 912 representing that the switch is in the first state (e.g., an off state, or S₀ state in FIG. 10), in step 1154. Control circuit 902 can then reenter the sleep state in step 1152, and the third measurement cycle ends.

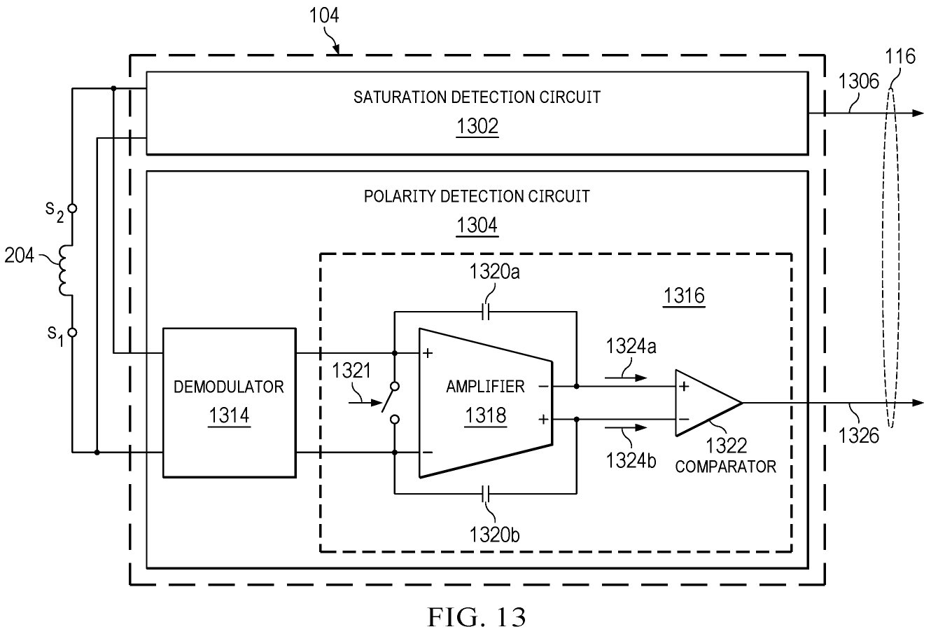

FIG. 13 illustrates a schematic of example internal components of processing circuit 104. Referring to FIG. 13, processing circuit 104 can include a saturation detection circuit 1302 and a polarity detection circuit 1304, both coupled to terminals s1 and s2 of sense coil 204 and receive Vₛ₁ and Vₛ₂ voltages. Saturation detection circuit 1302 can detect coil saturation based on Vₛ₁ and Vₛ₂ voltages and generate a saturation signal 1306. In some examples, saturation detection circuit 1302 can include an edge detector to detect transition edges of the Vₛ₁ and Vₛ₂ voltages, and provide saturation signal 1306 having a first state to indicate core saturation (by the external magnetic field) if no transition edge is detected. In some examples, saturation detection circuit 1302 can include an integrator to integrate Vₛ₁ and Vₛ₂ voltage pulses (if any), and compare the integrated voltage with a threshold. The integrated voltage being below the threshold can also indicate core saturation, and saturation detection circuit 1302 can provide saturation signal 1306 having the first state. On the other hand, if transition edges of the Vₛ₁ and Vₛ₂ voltages are detected, and/or the integrated voltage exceeds the threshold, saturation detection circuit 1302 can provide saturation signal 1306 having a second state to indicate that the core is not saturated by the external magnetic field.

Also, polarity detection circuit 1304 can include a demodulator 1314, a differential integrator 1316 including an amplifier 1318 and capacitors 1320a and 1320b, and a comparator 1322. Demodulator 1314 can convert the Vₛ₁ and Vₛ₂ voltage pulses to a particular polarity based on the polarities of the excitation current pulses, which reflect the excitation direction. Differential integrator 1316 can be reset by a reset signal 1321 at the beginning of a measurement cycle. After the reset signal is released, differential integrator 1316 can integrate the converted Vₛ₁ and Vₛ₂ voltage pulses to generate differential signals 1324a and 1324b. The relative magnitudes of differential signals 1324a and 1324b can reflect the polarity of the core magnetic field. Comparator 1322 can compare differential signals 1324a and 1324b and generate a comparison signal 1326. The state of comparison signal 1326 can indicate the polarity of core magnetic field. In some examples, comparator 1322 can include a dynamic latch-based/clocked comparator. Comparator 1322 can perform a comparison and generate comparison signal 1326 in every measurement cycle (e.g., after 2^{nd} excitation pulse), and then hold the state of comparison signal 1326. Processing circuit 104 can include saturation signal 1306 and comparison signal 1326 as result signal 116.

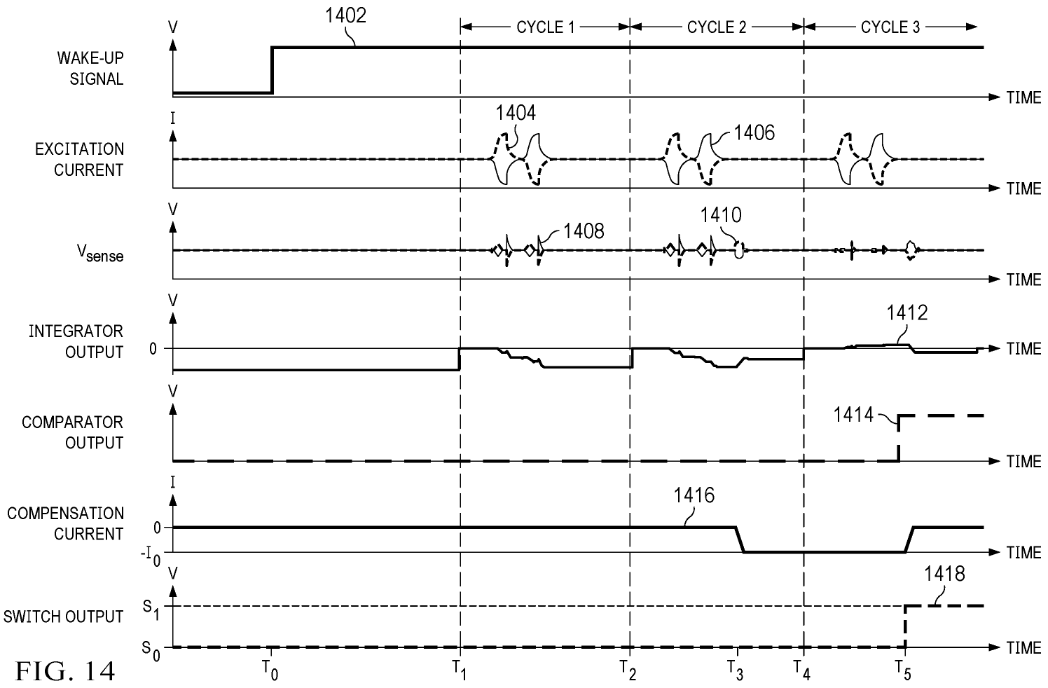

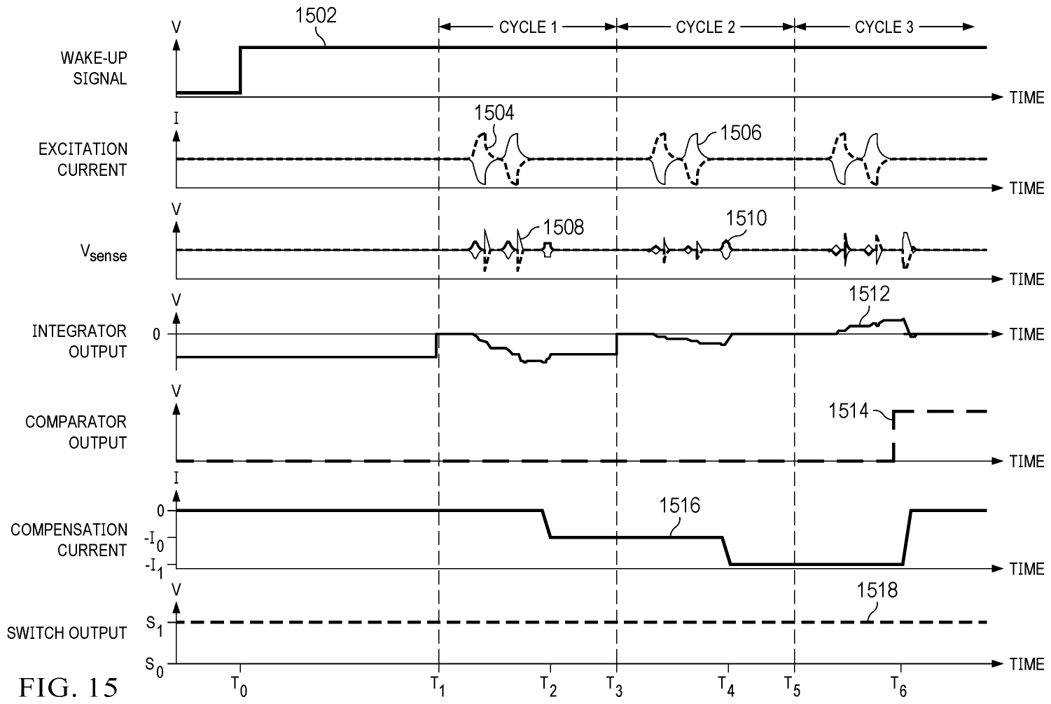

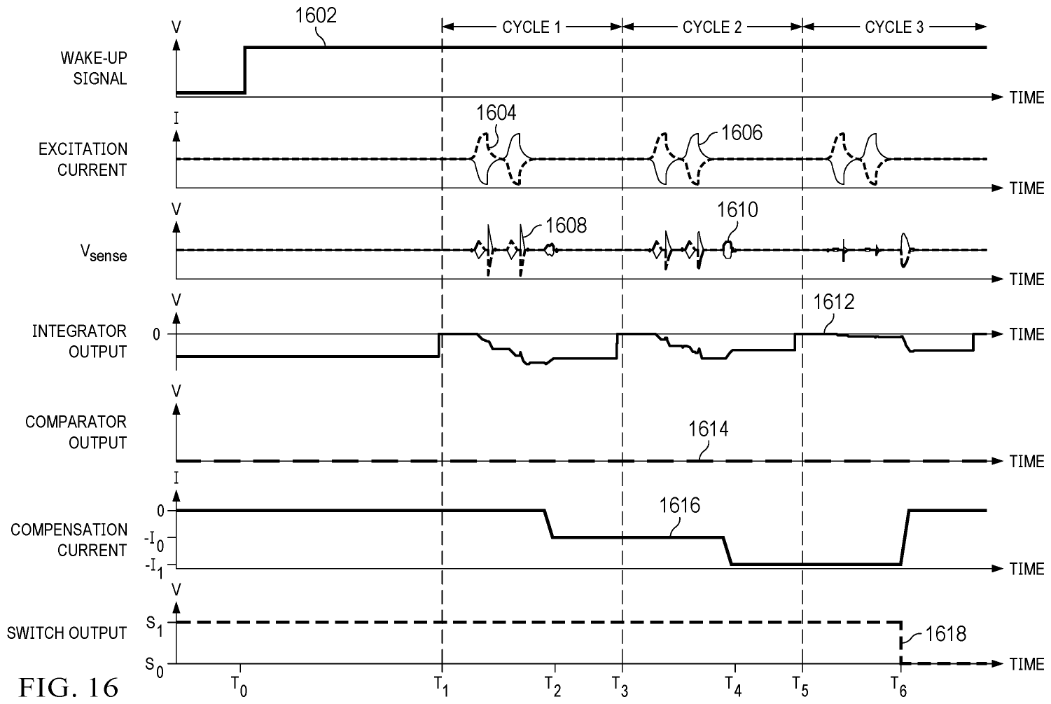

FIG. 14, FIG. 15, and FIG. 16 include graphs that illustrate example operations of sensor system 900 in measuring external magnetic field of different strengths. FIG. 14 illustrates example operations of sensor system 900 in measuring an external magnetic field strength that is below Bₜₕ₀ of FIG. 10. FIG. 15 illustrates example operations of sensor system 900 in measuring an external magnetic field strength between Bₜₕ₀ and Bₜₕ₁ of FIG. 10. Also, FIG. 16 illustrates example operations of sensor system 900 in measuring an external magnetic field strength that exceeds Bₜₕ₁ of FIG. 10.

FIG. 14 illustrates example operations of sensor system 900 in measuring an external magnetic field strength below Bₜₕ₀ of FIG. 10. FIG. 14 includes graphs 1402, 1404, 1406, 1408, 1410, 1412, 1414, 1416, and 1418. Graph 1402 illustrates example variations of wake-up signal 914 with time, graphs 1404 and 1406 illustrate example variations of excitation current I_{comp} with time, and graphs 1408 and 1410 illustrate example variations of Vₛₑₙₛₑ voltage across sense coil 204 with time. Also, graph 1412 illustrates example variation of differential output of integrator 1316 (e.g., a difference signal 1324a between signal 1324b) with time, graph 1414 illustrates example variation of comparison signal 1326 with time, graph 1416 illustrates example variation of compensation current (I_{comp}) with time, and graph 1418 illustrates example variation of switch output (represented by output signal 912) with time.

Referring to FIG. 14, control circuit 902 detects a transition of wake-up signal 914 at time TO, and exits the sleep state. Control circuit 902 can start a first measurement cycle (labelled “cycle 1”), which spans between times T₁ and T₂. In the first measurement cycle, control circuit 902 determines whether cores 202a/202b are saturated by an external magnetic field having the strength of Bₑₓₜ, and cause DAC 904 to provide zero compensation current (I_{comp}), so that compensation coil 704 provides no compensation magnetic field. Control circuit 902 causes excitation circuit 210 to provide a first pair of excitation current pulses having opposite polarities to excitation coil 203, and then receive saturation signal 1306 to determine whether cores 202a/202b are saturated by the external magnetic field. In the example of FIG. 14, because cores 202a/202b are not saturated by the external magnetic field, saturation detection circuit 1302 can detect Vₛₑₙₛₑ voltage pulses across sense coil 204, and provide saturation signal 1306 indicating no core saturation. Also, differential integrator 1316 exits the reset state at T₁ and integrates the Vₛₑₙₛₑ voltage pulses, and the differential output of integrator 1316 can reduce to below zero during the integration. Because the differential output of integrator 1316 is below zero, the output of comparator 1322 can be in a first state (e.g., a de-asserted state). Control circuit 902 can provide output signal 912 representing the prior switch state (S₀ in the example of FIG. 14) because the measurement of the external magnetic field is not yet complete.

After determining that cores 202a/202b are not saturated by the external magnetic field in the first measurement cycle, control circuit 902 can start a second measurement cycle (labelled “cycle 2”), which spans between times T₂ and T₄. In the second measurement cycle, control circuit 902 determines the polarity of the external magnetic field, and cause DAC 904 to provide zero compensation current (I_{comp}), so that compensation coil 704 provides no compensation magnetic field. Control circuit 902 causes excitation circuit 210 to provide a second pair of excitation current pulses having opposite polarities to excitation coil 203. The external magnetic field can introduce Vₛₑₙₛₑ voltage pulses across sense coil 204. Differential integrator 1316 exits the reset state at T₂ and integrates the Vₛₑₙₛₑ voltage pulses. The differential output of integrator 1316 reduces during the integration to below zero, and the output of comparator 1322 can remain in the first state (a de-asserted state), which indicates a first polarity of the external magnetic field. The switch state represented by output signal 912 of control circuit 902 can remain in the prior switch state (S₀ in FIG. 14) because the measurement of the external magnetic field is not yet complete.

Also, before the end of the second measurement cycle, control circuit 902 can select −I₀ from mapping table 906 based on the polarity of the external magnetic field. Control circuit 902 can then transmit control signal 910 indicating −I₀ to DAC 904 at time T₃. DAC 904 can then provide a compensation current of −I₀ to compensation coil 704 to generate a compensation magnetic field having the strength of Bₜₕ₀ and having a second polarity opposite to the first polarity of the external magnetic field. The compensation magnetic field can subtract from the external magnetic field to generate a core magnetic field having a net strength of difference between Bₑₓₜ and Bₜₕ₀ (Bₑₓₜ−Bₜₕ₀). The core magnetic field can have the same polarity as the external magnetic field if Bₑₓₜ exceeds Bₜₕ₀. The core magnetic field can have opposite polarity to the external magnetic field if Bₑₓₜ is below Bₜₕ₀.

Control circuit 902 can then start a third measurement cycle (labelled “cycle 3”) at time T₄, to determine the polarity of the core magnetic field. Control circuit 902 causes excitation circuit 210 to provide a third pair of excitation current pulses having opposite polarities to excitation coil 203. The core magnetic field can introduce Vₛₑₙₛₑ voltage pulses across sense coil 204. Differential integrator 1316 exits the reset state at T₄ and integrates the Vₛₑₙₛₑ voltage pulses. In the example of FIG. 14, Bₑₓₜ is below Bₜₕ₀, and the core magnetic field has the opposite polarity to the external magnetic field. Accordingly, the differential output of integrator 1316 increases during the integration to above zero, and the output of comparator 1322 can switch to a second state (an asserted state) at time T₅. Responsive to the comparator output being at the second state, control circuit 902 can provide output signal 912 representing the S₁ state (e.g., on state) to indicate that Bₑₓₜ is below Bₜₕ₀. Control circuit 902 can then re-enter the sleep state and disable DAC 904, and the compensation current can return back to zero after time T₅.

FIG. 15 illustrates the example operations of sensor system 900 in measuring an external magnetic field having a strength between Bₜₕ₀ and Bₜₕ₁ of FIG. 10. FIG. 15 includes graphs 1502, 1504, 1506, 1508, 1510, 1512, 1514, 1516, and 1518. Graph 1502 illustrates example variations of wake-up signal 914 with time, graphs 1504 and 1506 illustrate example variations of excitation current I_{comp} with time, and graphs 1508 and 1510 illustrate example variations of Vₛₑₙₛₑ voltage across sense coil 204 with time. Also, graph 1512 illustrates example variation of differential output of integrator 1316 (e.g., a difference signal 1324a between signal 1324b) with time, graph 1514 illustrates example variation of comparison signal 1326 with time, graph 1516 illustrates example variation of compensation current (I_{comp}) with time, and graph 1518 illustrates example variation of switch output (represented by output signal 912) with time.

Referring to FIG. 15, control circuit 902 detects a transition of wake-up signal 914 at time TO, and exits the sleep state. Control circuit 902 can start a first measurement cycle (labelled “cycle 1”), which spans between times T₁ and T₃. In the first measurement cycle, control circuit 902 determines whether cores 202a/202b are saturated by an external magnetic field having the strength of Bₑₓₜ, and if the cores are not saturated, measure a polarity of the external magnetic field. Accordingly, in the first measurement cycle, control circuit 902 causes DAC 904 to provide zero compensation current (I_{comp}), so that compensation coil 704 provides no compensation magnetic field. Control circuit 902 causes excitation circuit 210 to provide a first pair of excitation current pulses having opposite polarities to excitation coil 203, and then receive saturation signal 1306 to determine whether cores 202a/202b are saturated by the external magnetic field. In the example of FIG. 15, because cores 202a/202b are not saturated by the external magnetic field, saturation detection circuit 1302 can detect Vₛₑₙₛₑ voltage pulses across sense coil 204, and provide saturation signal 1306 indicating no core saturation. Also, differential integrator 1316 exits the reset state at T₁ and integrates the Vₛₑₙₛₑ voltage pulses, and the differential output of integrator 1316 reduces during the integration to below zero. Because the differential output of integrator 1316 is below zero, the output of comparator 1322 can be in a first state (e.g., a de-asserted state), which indicates a first polarity of the external magnetic field. Control circuit 902 can provide output signal 912 representing the prior switch state (S₁ in the example of FIG. 15) because the measurement of the external magnetic field is not yet complete.

Before the end of the first measurement cycle, at time T₂, control circuit 902 can select −I₀ from mapping table 906 based on the first polarity of the external magnetic field. Control circuit 902 can then transmit control signal 910 indicating −I₀ to DAC 904 at time T₂. DAC 904 can then provide a compensation current of −I₀ to compensation coil 704 to generate a first compensation magnetic field having the strength of Bₜₕ₀ and having a second polarity opposite to the first polarity of the external magnetic field. The first compensation magnetic field can subtract from the external magnetic field to generate a first core magnetic field having a net strength of Bₑₓₜ−Bₜₕ₀. The first core magnetic field can have the same first polarity as the external magnetic field if Bₑₓₜ exceeds Bₜₕ₀. The first core magnetic field can have the second polarity (opposite to the first polarity of the external magnetic field) if Bₑₓₜ is below Bₜₕ₀.

Control circuit 902 can then start a second measurement cycle (labelled “cycle 2”), which spans between times T₃ and T₅. In the second measurement cycle, control circuit 902 determines the polarity of the first core external magnetic field. Control circuit 902 causes excitation circuit 210 to provide a second pair of excitation current pulses having opposite polarities to excitation coil 203. The first core magnetic field can introduce Vₛₑₙₛₑ voltage pulses across sense coil 204. Differential integrator 1316 exits the reset state at T₃ and integrates the Vₛₑₙₛₑ voltage pulses, and the differential output of integrator 1316 reduces during the integration to below zero. The output of comparator 1322 can remain in the first state (a de-asserted state), which indicates that the first core magnetic field has the first polarity. The switch state represented by output signal 912 of control circuit 902 can remain in the prior switch state (S₁ in FIG. 15) because the measurement of the external magnetic field is not yet complete.

Before the end of the second measurement cycle, at time T₄, control circuit 902 can select −I₁ from mapping table 906 based on the first polarity of the first core magnetic field. Control circuit 902 can then transmit control signal 910 indicating −I₁ to DAC 904 at time T₄. DAC 904 can then provide a compensation current of −I₁ to compensation coil 704 to generate a second compensation magnetic field having the strength of Bₜₕ₁ and having the second polarity. The second compensation magnetic field can subtract from the external magnetic field to generate a second core magnetic field having a net strength of difference between Bₑₓₜ and Bₜₕ₁ (Bₑₓₜ−Bₜₕ₁). The second core magnetic field can have the same first polarity as the external magnetic field if Bₑₓₜ exceeds Bₜₕ₁. The second core magnetic field can have the second polarity (opposite to the first polarity of the external magnetic field) if Bₑₓₜ is below Bₜₕ₁.

Control circuit 902 can then start a third measurement cycle (labelled “cycle 3”) at time T₅, to determine the polarity of the second core magnetic field. Control circuit 902 causes excitation circuit 210 to provide a third pair of excitation current pulses having opposite polarities to excitation coil 203. The core magnetic field can introduce Vₛₑₙₛₑ voltage pulses across sense coil 204. Differential integrator 1316 exits the reset state at T₅ and integrates the Vₛₑₙₛₑ voltage pulses. In the example of FIG. 15, Bₑₓₜ is below Bₜₕ₁, and the second core magnetic field has the opposite polarity to the external magnetic field. Accordingly, the differential output of integrator 1316 increases during the integration to above zero, and the output of comparator 1322 can switches to a second state (an asserted state) at time T₆. Responsive to the comparator output at the second state, control circuit 902 can provide output signal 912 representing the S₁ state (e.g., on state) to indicate that Bₑₓₜ is between Bₜₕ₀ and Bₜₕ₁. Control circuit 902 can then re-enter the sleep state and disable DAC 904, and compensation current returns back to zero after time T₆.

FIG. 16 illustrates the example operations of sensor system 900 in measuring an external magnetic field strength that exceeds Bₜₕ₁ of FIG. 10. FIG. 16 includes graphs 1602, 1604, 1606, 1608, 1610, 1612, 1614, 1616, and 1618. Graph 1602 illustrates example variations of wake-up signal 914 with time, graphs 1604 and 1606 illustrate example variations of excitation current ICOMP with time, and graphs 1608 and 1610 illustrate example variations of Vₛₑₙₛₑ voltage across sense coil 204 with time. Also, graph 1612 illustrates example variation of differential output of integrator 1316 (e.g., a difference between signal 1324a and signal 1324b) with time, graph 1614 illustrates example variation of comparison signal 1326 with time, graph 1616 illustrates example variation of compensation current (I_{comp}) with time, and graph 1618 illustrates example variation of switch output (represented by output signal 912) with time.

Referring to FIG. 16, control circuit 902 detects a transition of wake-up signal 914 at time T0, and exits the sleep state. Control circuit 902 can start a first measurement cycle (labelled “cycle 1”), which spans between times T₁ and T₃. In the first measurement cycle, control circuit 902 determines whether cores 202a/202b are saturated by an external magnetic field having the strength of Bₑₓₜ, and if the cores are not saturated, measure a polarity of the external magnetic field. Accordingly, in the first measurement cycle, control circuit 902 causes DAC 904 to provide zero compensation current (I_{comp}), so that compensation coil 704 provides no compensation magnetic field. Control circuit 902 causes excitation circuit 210 to provide a first pair of excitation current pulses having opposite polarities to excitation coil 203, and then receive saturation signal 1306 to determine whether cores 202a/202b are saturated by the external magnetic field. In the example of FIG. 16, because cores 202a/202b are not saturated by the external magnetic field, saturation detection circuit 1302 can detect Vₛₑₙₛₑ voltage pulses across sense coil 204, and provide saturation signal 1306 indicating no core saturation. Also, differential integrator 1316 exits the reset state at T₁ and integrates the Vₛₑₙₛₑ voltage pulses, and the output of integrator 1316 reduces during the integration to below zero. Because the output of integrator 1316 is below zero, the output of comparator 1322 can be in a first state (e.g., a de-asserted state), which indicates a first polarity of the external magnetic field. Control circuit 902 can provide output signal 912 representing the prior switch state (S₁ in the example of FIG. 16) because the measurement of the external magnetic field is not yet complete.

Before the end of the first measurement cycle, at time T₂, control circuit 902 can select −I₀ from mapping table 906 based on the first polarity of the external magnetic field. Control circuit 902 can then transmit control signal 910 indicating −I₀ to DAC 904 at time T₂. DAC 904 can then provide a compensation current of −I₀ to compensation coil 704 to generate a first compensation magnetic field having the strength of Bₜₕ₀ and having a second polarity opposite to the first polarity of the external magnetic field. The first compensation magnetic field can subtract from the external magnetic field to generate a first core magnetic field having a net strength of Bₑₓₜ−Bₜₕ₀. The first core magnetic field can have the same first polarity as the external magnetic field if Bₑₓₜ exceeds Bₜₕ₀. The first core magnetic field can have the second polarity (opposite to the first polarity of the external magnetic field) if Bₑₓₜ is below Bₜₕ₀.

Control circuit 902 can then start a second measurement cycle (labelled “cycle 2”), which spans between times T₃ and T₅. In the second measurement cycle, control circuit 902 determines the polarity of the first core external magnetic field. Control circuit 902 causes excitation circuit 210 to provide a second pair of excitation current pulses having opposite polarities to excitation coil 203. The first core magnetic field can introduce Vₛₑₙₛₑ voltage pulses across sense coil 204. Differential integrator 1316 exits the reset state at T₃ and integrates the Vₛₑₙₛₑ voltage pulses, and the differential output of integrator 1316 reduces during the integration to below zero, and the output of comparator 1322 can remain in the first state (a de-asserted state), which indicates that the first core magnetic field has the first polarity. The switch state represented by output signal 912 of control circuit 902 can remain in the prior switch state (S₁ in FIG. 15) because the measurement of the external magnetic field is not yet complete.

Before the end of the second measurement cycle, at time T₄, control circuit 902 can select −I₁ from mapping table 906 based on the first polarity of the first core magnetic field. Control circuit 902 can then transmit control signal 910 indicating −I₁ to DAC 904 at time T₄. DAC 904 can then provide a compensation current of −I₁ to compensation coil 704 to generate a second compensation magnetic field having the strength of Bₜₕ₁ and having the second polarity. The second compensation magnetic field can subtract from the external magnetic field to generate a second core magnetic field having a net strength of Bₑₓₜ−Bₜₕ₁. The second core magnetic field can have the same first polarity as the external magnetic field if Bₑₓₜ exceeds Bₜₕ₁. The second core magnetic field can have the second polarity (opposite to the first polarity of the external magnetic field) if Bₑₓₜ is below Bₜₕ₁.

Control circuit 902 can then start a third measurement cycle (labelled “cycle 3”) at time T₅, to determine the polarity of the second core magnetic field. Control circuit 902 causes excitation circuit 210 to provide a third pair of excitation current pulses having opposite polarities to excitation coil 203. The core magnetic field can introduce Vₛₑₙₛₑ voltage pulses across sense coil 204. Differential integrator 1316 exits the reset state at T₅ and integrates the Vₛₑₙₛₑ voltage pulses. In the example of FIG. 16, Bₑₓₜ is above Bₜₕ₁, and the second core magnetic field has the same first polarity as the external magnetic field. Accordingly, the differential output of integrator 1316 decreases during the integration to below zero, and the output of comparator 1322 can remain in the first state (de-asserted state) at time T₆. Responsive to the comparator output at the first state, control circuit 902 can provide output signal 912 representing the S₀ state (e.g., off state) to indicate that Bₑₓₜ is above Bₜₕ₁. Control circuit 902 can then re-enter the sleep state and disable DAC 904, and compensation current returns back to zero after time T₆.

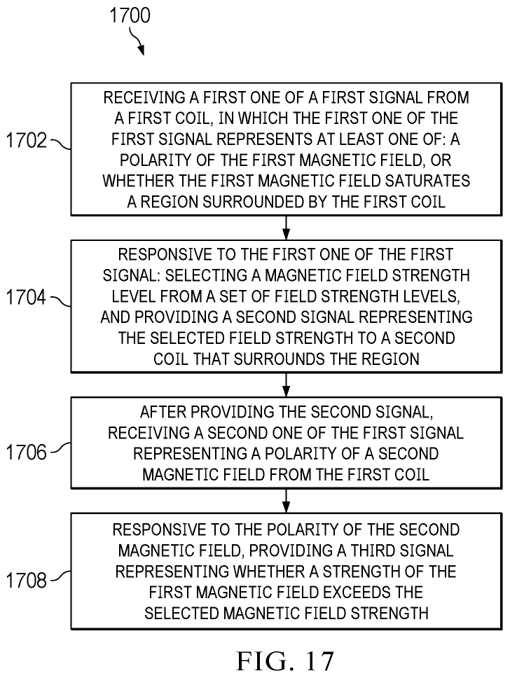

FIG. 17 illustrates a flowchart of an example method 1700 of measuring a magnetic field. Method 1700 can be performed by a sensor system, such as sensor system 900, to measure the strength and polarity of an external magnetic field. Method 1700 can be performed by a control circuit (e.g., control circuit 902) in conjunction with other components of sensor system 900, including fluxgate magnetic sensor 702, processing circuit 104, excitation circuit 210, and DAC 904. Method 1700 can include operations described in flowchart 1100 of FIGS. 11A-11C.

In step 1702, the control circuit can receive a first one of a first signal from a first coil, in which the first one of the first signal indicates at least one of: a polarity of a first magnetic field, or whether the first magnetic field saturates a region surrounded by the first coil.

Specifically, the first magnetic field can be a first core magnetic field sensed by sense coil 204. The first core magnetic field can result from an external magnetic field propagating through a core (or a region) surrounded by the first coil (e.g., cores 202a/202b) having a strength of Bₑₓₜ. In some examples, the control circuit may control compensation coil 704 to generate a first compensation magnetic field having a strength of Bₜₕ₀ and an opposite polarity to the external magnetic field prior to step 1702, and the first core magnetic field can be a combination of the external magnetic field and the first compensation magnetic field and have a net strength of Bₑₓₜ−Bₜₕ₀. The first signal can include comparison signal 1326 from comparator 1322 and/or saturation signal 1306 from saturation detection circuit 1302.

In step 1704, responsive to the first one of the first signal, the control circuit can select a magnetic field strength level from a set of magnetic field strength levels for generating a compensation magnetic field, and provide a second signal representing the selected magnetic field to a second coil that surrounds the region.

Specifically, the second coil can be compensation coil 704. In some examples, if the first one of the first signal indicates the core/core region is not saturated by the first magnetic field, and no compensation magnet field is present, control circuit 902 can select a magnetic field strength level (e.g., Bₜₕ₀ or Bₜₕ₁ of FIG. 10). Control circuit 902 can also determine a first polarity of the first magnetic field, and control compensation coil 704 to generate the first compensation magnetic field having the strength Bₜₕ₀ and a second polarity opposite to the first polarity. Also, if the first magnetic field is a combination of the external magnetic field and the first compensation magnetic field, control circuit can control compensation coil 704 to generate a second compensation magnetic field having the strength having the strength Bₜₕ₁ and the second polarity opposite to the first polarity.

In step 1706, after providing the second signal, the control circuit can receive a second one of the first signal representing a polarity of a second magnetic field from the first coil.

Specifically, the second magnetic field can result from a combination of the external magnetic field and one of the first or second compensation magnetic fields, and the second magnetic field can have a net strength of Bₑₓₜ−Bₜₕ₀ or Bₑₓₜ−Bₜₕ₁. The second one of the first signal can indicate whether Bₑₓₜ exceeds Bₜₕ₀, or whether Bₑₓₜ exceeds Bₜₕ₁.

In step 1708, responsive to the polarity of the second magnetic field, the control circuit can provide a third signal representing whether a strength of the first magnetic field (or the external magnetic field) exceeds the selected magnetic field strength.

Specifically, as described above, sensor system 900 can implement a fluxgate ominipolar switch having a transfer characteristic similar to the one illustrated in FIG. 10, where the third signal can represent a state of the switch. For example, if the external magnetic field strength is below Bₜₕ₀, control circuit 902 can output a switch state of S₁ (e.g., a logic one or an on state). Also, if the external magnetic field strength is above Bₜₕ₁, control circuit 902 can output a switch state of S₀ (e.g., a logic zero or an off state). Further, if the external magnetic field strength is between Bₜₕ₀ and Bₜₕ₁, control circuit 902 can maintain the switch state to provide built-in hysteresis. The switch state can indicate a range of the external magnetic field strength. In a case sensor system 900 performs comparison between the external magnetic field strength and zero strength level, the state third signal can also represent the polarity of the external magnetic field.

Any of the methods described herein may be totally or partially performed with a computing system, such as a processor, a microcontroller, etc., which can be configured to perform the steps. Thus, embodiments can be directed to computing systems configured to perform the steps of any of the methods described herein, potentially with different components performing a respective steps or a respective group of steps. Although presented as numbered steps, steps of methods herein can be performed at a same time or in a different order. Additionally, portions of these steps may be used with portions of other steps from other methods. Also, all or portions of a step may be optional. Additionally, any of the steps of any of the methods can be performed with modules, units, circuits, or other means for performing these steps.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described herein as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

Certain components may be described herein as being of a particular process technology, but these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor.

Uses of the phrase “ground voltage potential” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible, within the scope of the claims.

What is claimed is:

1. An apparatus comprising:
a first coil;
a second coil magnetically coupled to the first coil;
a control circuit having a control input and a signal output, the signal output coupled to the first coil, and the control circuit configured to:
responsive to a state of the control input, select a field strength level from a set of discrete field strength levels; and
provide a first signal representing the selected field strength level at the signal output; and
a processing circuit having processing inputs and a processing output, the processing inputs coupled to the second coil, the processing output coupled to the control input, and the processing circuit configured to, responsive to a second signal across the processing inputs, set a state of the processing output representing a polarity of a magnetic field sensed by the second coil.

2. The apparatus of claim 1, further comprising a core surrounded by the first and second coils.

3. The apparatus of claim 1, wherein:
the first coil is configured to generate a compensation magnetic field responsive to the first signal, the compensation magnetic field having an opposite polarity from an external magnetic field;
the second coil is configured to generate the second signal responsive to a combined magnetic field, in which the combined magnetic field includes a combination of the external magnetic field and the compensation magnetic field; and
the state of the processing output represents the polarity of the combined magnetic field.

4. The apparatus of claim 3, wherein the first signal indicates that the compensation magnetic field has a zero strength.

5. The apparatus of claim 3, wherein the control circuit has a control output, and the control circuit is configured to set a state of the control output responsive to the state of the control input, the state of the control output representing a relationship between a strength of the external magnetic field and the set of discrete field strength levels.

6. The apparatus of claim 5, wherein the control circuit is configured to set the control output to a first state responsive to the state of the control input representing that the combined magnetic field has an opposite polarity to the external magnetic field.

7. The apparatus of claim 6, wherein the control output having the first state represents that the strength of the external magnetic field is below the selected field strength level.

8. The apparatus of claim 6, wherein the control circuit is configured to set the control output to a second state responsive to the state of the control input representing that the external magnetic field saturates a region surrounded by the first and second coils, and if the compensation magnetic field has a zero strength.

9. The apparatus of claim 6, wherein the selected field strength level is a first field strength level, the compensation magnetic field is a first compensation magnetic field, the combined magnetic field is a first combined magnetic field, and the control circuit is configured to, responsive to the state of the control input indicating that the first combined magnetic field has a same polarity as the external magnetic field:
select a second field strength level from the set of discrete field strength levels, the second field strength level being higher than the first field strength level; and
provide the first signal representing the second field strength level at the signal output;
wherein the first coil is configured to generate a second compensation magnetic field responsive to the first signal representing the second field strength level; and
wherein the second coil is configured to provide the second signal responsive to a second combined magnetic field, the second combined magnetic field being a combination of the external magnetic field and the second compensation magnetic field.

10. The apparatus of claim 9, wherein the control circuit is configured to set the control output to a second state responsive to the state of the control input representing that the second combined magnetic field has a same polarity as the external magnetic field.

11. The apparatus of claim 10, wherein the control output having the second state represents that the strength of the external magnetic field is above the second field strength level.

12. The apparatus of claim 10, wherein the control output has one of the first state or a second state before the control circuit provides the first signal representing the second field strength level at the signal output; and
wherein the control circuit is configured to set the control output to the one of the first state or the second state responsive to the state of the control input representing that the second combined magnetic field has an opposite polarity to the external magnetic field.

13. The apparatus of claim 1, further comprising:
a third coil magnetically coupled to the first and second coils; and
an excitation circuit having an excitation output coupled to the third coil, and the excitation circuit configured to provide an excitation signal at the excitation output.

14. The apparatus of claim 13, wherein:
the selected field strength level is a first field strength level;
in a first measurement cycle:
the excitation circuit is configured to provide a first pulse as the excitation signal at the excitation output;
the control circuit is configured to provide the first signal representing the first field strength level; and
in a second measurement cycle:
the excitation circuit is configured to provide a second pulse as the excitation signal at the excitation output; and
the control circuit is configured to:
select a second field strength level from the set of field strength levels; and
provide the first signal representing the second field strength level.

15. The apparatus of claim 14, wherein the excitation circuit is configured to provide a third pulse and the first pulse in the first measurement cycle, and provide a fourth pulse and the second pulse in the second measurement cycle; and
wherein the first and third pulses have opposite polarities, and the second and fourth pulses have opposite polarities.

16. The apparatus of claim 1, wherein the first and second coils are encapsulated in a magnetic molding compound.

17. The apparatus of claim 1, wherein the processing circuit includes:
an integrator having integrator inputs and integrator outputs, the integrator inputs coupled to the processing inputs; and
a comparator having comparator inputs and a comparator output, the comparator inputs coupled to the integrator outputs, and the comparator output coupled to the processing output.

18. An apparatus comprising:
a control circuit having a control input and a compensation magnetic field control output, the control circuit configured to:
responsive to a state of the control input, select a field strength level from a set of discrete field strength levels; and
provide a first signal representing the selected field strength level at the compensation magnetic field control output; and
a processing circuit having a magnetic field sensing input and a processing output, the processing output coupled to the control input, and the processing circuit configured to, responsive to a second signal at the magnetic field sensing input, set a state of the processing output representing a polarity of a magnetic field.

19. The apparatus of claim 18, further comprising:
a first coil coupled to the compensation magnetic field control output; and
a second coil coupled to the magnetic field sensing input, and the second coil configured to sense the magnetic field in a region surrounded by the first and second coils.

20. A method comprising:
receiving a first one of a first signal from a first coil, in which the first one of the first signal represents at least one of: a polarity of a first magnetic field, or whether the first magnetic field saturates a region surrounded by the first coil;
responsive to the polarity of the first magnetic field, selecting a field strength level from a set of discrete field strength levels, and providing a second signal representing the selected field strength level to a second coil that surrounds the region;
after providing the second signal, receiving a second one of the first signal representing a polarity of a second magnetic field from the first coil; and
responsive to the polarity of the second magnetic field, providing a third signal representing whether a strength of the first magnetic field exceeds the selected field strength level.

21. The method of claim 20, wherein the first one of the first signal indicates at least one of: the first magnetic field does not saturate the region, or a polarity of the first magnetic field.

22. The method of claim 20, wherein the second signal causes the second coil to generate a third magnetic field having an opposite polarity to the first magnetic field and having the selected field strength level; and
wherein the second magnetic field is a combination of the first and third magnetic fields.

23. The method of claim 20, wherein the second signal is a first one of the second signal, the field strength level is a first field strength level, and the method further comprises:
responsive to the polarity of the second magnetic field, selecting a second field strength level from the set of field strength levels, the second field strength level exceeding the first field strength level;
providing a second one of the second signal representing the second field strength level to the second coil; and
after providing the second one of the second signal, receiving a third one of the first signal representing a polarity of a fourth magnetic field from the first coil; and
responsive to polarity of the fourth magnetic field, providing the third signal representing whether a strength of the first magnetic field exceeds the second field strength level.
